(19) United States
(12) Patent Application Publication
(10) Pub. No.: US 2026/0107404 A1
(43) Pub. Date: Apr. 16, 2026

(54) CENTRAL SWITCH DISTRIBUTION COLUMN FOR COMPUTING DEVICE

(71) Applicant: Microsoft Technology Licensing, LLC, Redmond, WA (US)

(72) Inventor: Jason David ADRIAN, Woodinville, WA (US)

(73) Assignee: Microsoft Technology Licensing, LLC, Redmond, WA (US)

(21) Appl. No.: 18/917,267

(22) Filed: Oct. 16, 2024

(51) Int. Cl. H05K 7/14

(52) U.S. Cl. CPC H05K 7/1487; H05K 7/1452; H05K 7/1489; H05K 7/1491

(57) ABSTRACT

A computing device assembly is presented. The computing device assembly comprises a rack and a plurality of compute units that are horizontally oriented and mounted within the rack in first and second vertical stacks. A plurality of switches are vertically oriented and mounted along the rack in a first bank of switches and a second bank of switches. A first set of horizontal cable backplanes are mounted in a first vertical assembly along an interior side of the first vertical stack. A second set of horizontal cable backplanes are mounted in a first vertical assembly along an interior side of the second vertical stack. A central switch distribution column is communicatively coupled to the first and second sets of horizontal cable backplanes and to the first and second banks of switches, such that each of the plurality of compute units is connected to each of the plurality of switches.

### BACKGROUND

Modern computing increasingly takes place in data center environments. Particularly with the rise of large machine learning (ML) models, the need for increased compute power has risen dramatically. The cost of deploying and operating compute units used to handle computing tasks such as model training and inference is significant. Further, the compute time required to train large ML models can be lengthy and costly, favoring systems with large numbers of processing units and intricate switch fabrics.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

A computing device assembly is presented. The computing device assembly comprises a rack and a plurality of compute units that are horizontally oriented and mounted within the rack in first and second vertical stacks. A plurality of switches are vertically oriented and mounted along the rack in a first bank of switches and a second bank of switches. A first set of horizontal cable backplanes are mounted in a first vertical array along an interior side of the first vertical stack. A second set of horizontal cable backplanes are mounted in a second vertical array along an interior side of the second vertical stack. A central switch distribution column is communicatively coupled to the first and second sets of horizontal cable backplanes and to the first and second banks of switches, such that each of the plurality of compute units is connected to each of the plurality of switches through the central switch distribution column.

### BRIEF DESCRIPTION OF THE DRAWINGS

FIG. 1 shows a top-down view of an example computing device assembly.

FIGS. 2-4 show perspective views of the computing device assembly of FIG. 1.

FIG. 5 shows a side-on view of the computing device assembly of FIGS. 1-4.

FIG. 6 shows a close-up view of the computing device assembly of FIGS. 1-5.

FIG. 7 shows an example wiring routing diagram for an example computing device assembly.

FIG. 8 shows a flow diagram for an example method for operating a computing device assembly.

FIG. 9 schematically shows an example computing system.

### DETAILED DESCRIPTION

Artificial intelligence (AI) systems require high bandwidth communication between accelerators and switch fabrics. Large accelerator counts are incredibly challenging at the data rates of contemporary technologies running over copper, which traditionally leads to small accelerator pod counts. These often range from 32 to 72 accelerators interconnected. Within a high-density AI system there are banks of accelerators (e.g., graphic processing units (GPUs)), which each must connect to every switch of the switch fabric. Positioning the switching apparatus in the center of the banks of accelerators can achieve some increase in accelerator count up to 192 or possibly 256 accelerators. However, there may be thousands or tens or thousands of differential pairs of wires that have to crisscross from each accelerator to each switch. This yields a very complicated mesh. At the same time, link speeds are increasing, which means each differential pair is limited in how long it can be—on the order of 2-3 meters. In order to scale up to 512 or more accelerators, the height of the computing device assembly could be increased, but if the height is doubled to accommodate twice as many accelerators, the top-to-bottom distance also doubles, and the signal quality decreases accordingly. Additional columns of accelerators can be added, but the number of switches also doubles, and the system becomes copper limited. Such an apparatus would at least require re-timers on every single lane, increasing production costs, and still may not be functional.

Herein, systems and methods are provided which allow for up to 512 accelerators or more to be positioned into a single computing device assembly. Compute units (accelerators) are provided in trays, which are grouped into up to four vertical stacks. Each vertical stack is provided with a horizontal cable backplane assembly. Each horizontal cable backplane assembly is coupled to a central switch distribution column. The central switch distribution column fans out cables to first and second banks of switches, located on opposite sides of the central switch distribution column. These systems enable a scale of 512 or more accelerators through interconnectivity over an H-shaped topology. By moving the switches to the center of the computing device assembly, interconnect distances are kept short enough to support 112G serialize/deserialize (SerDes) technology. Further the disclosed system ensures that the vast majority of the components are directly serviceable from the front or sides, which enables easy serviceability.

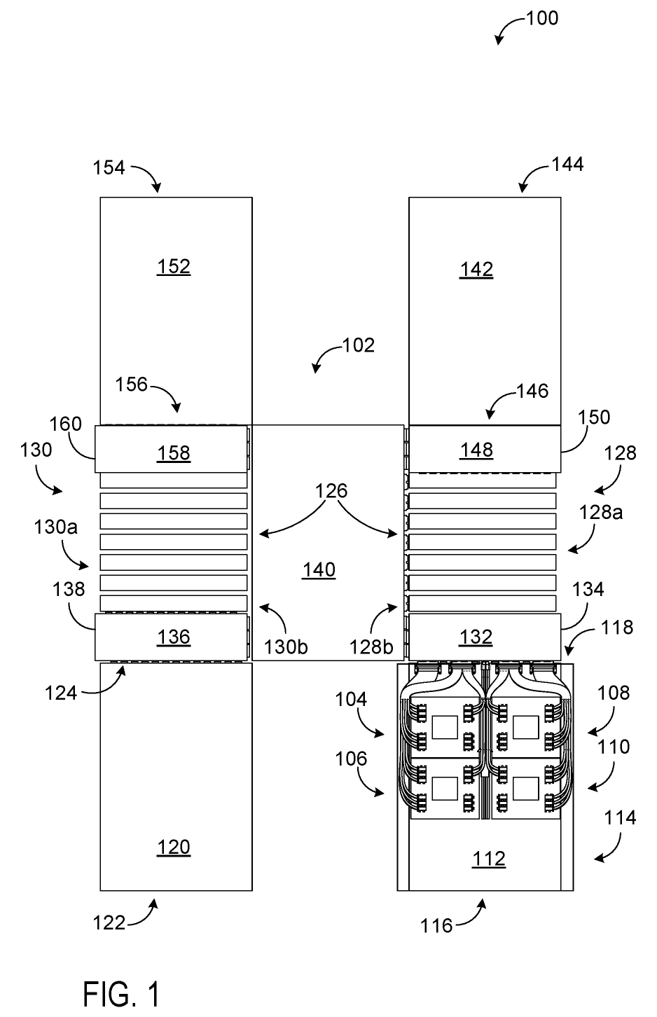

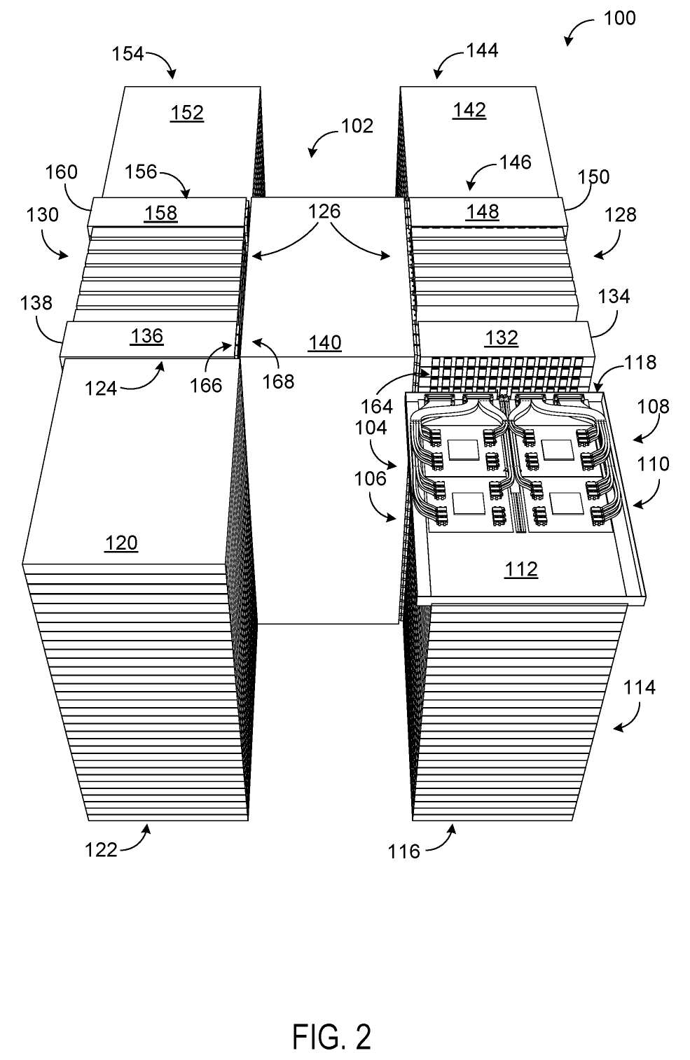

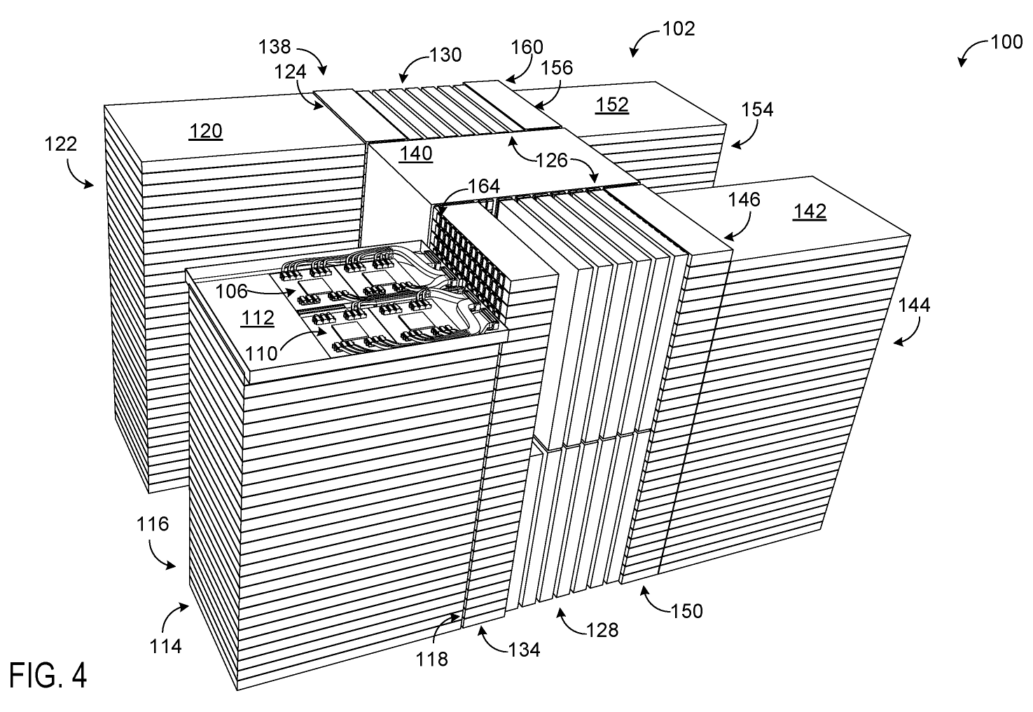

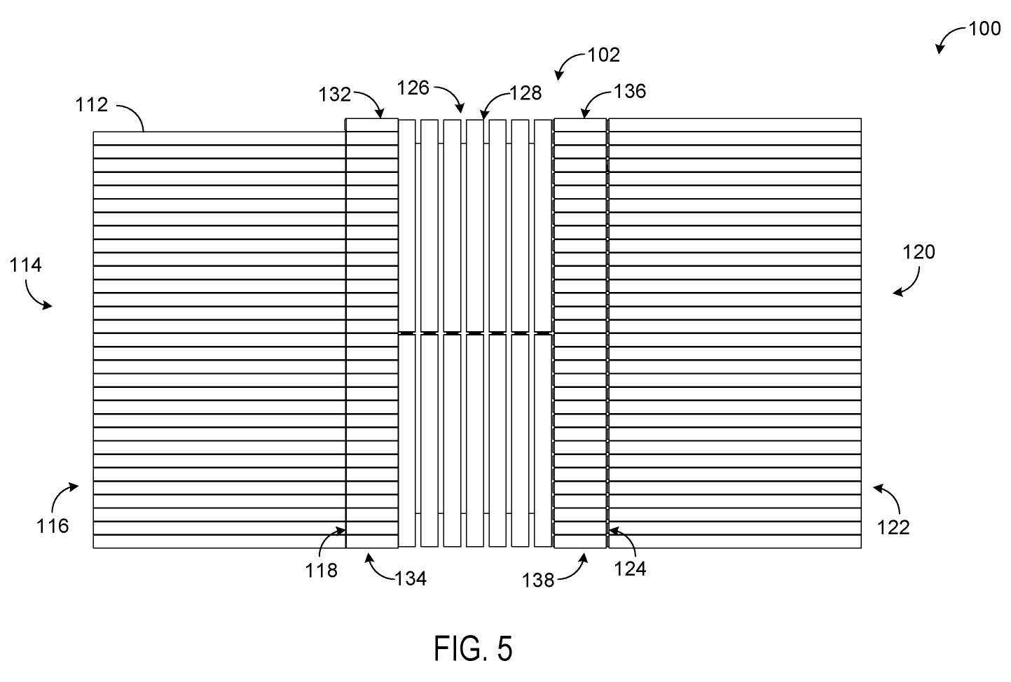

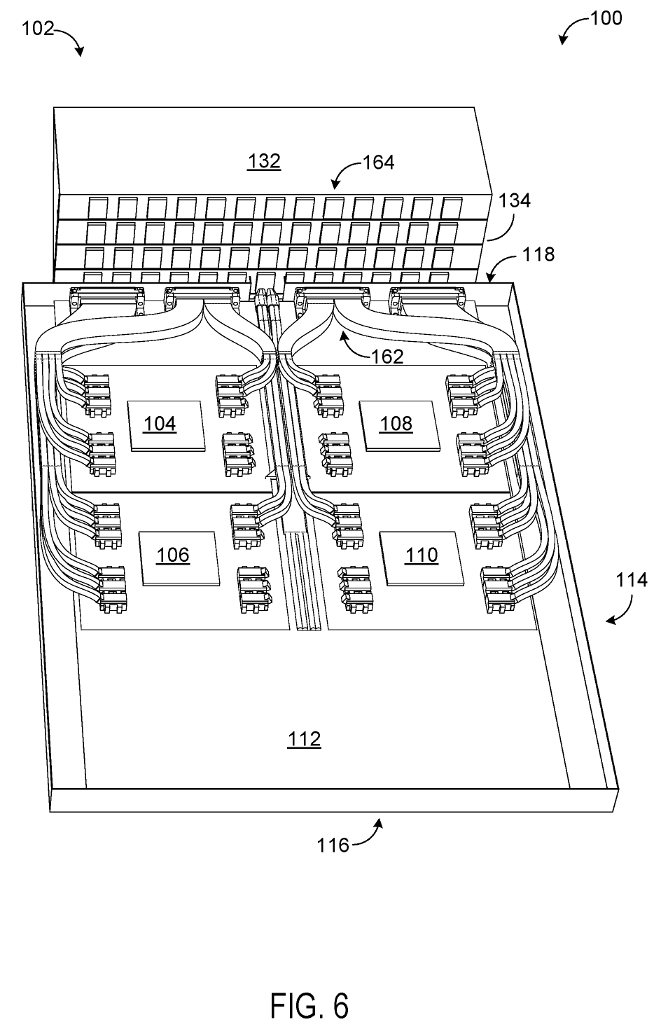

FIGS. 1-6 illustrate an example computing device assembly 100. Some components have been removed to aid in visualization of other, interior components. FIG. 1 shows a top-down view of computing device assembly 100. FIGS. 2-4 show perspective views of computing device assembly 100. FIG. 5 shows a side view of computing device assembly 100. FIG. 6 shows a close-up view of computing device assembly 100.

Computing device assembly 100 comprises rack 102 defining a volume. Computing device assembly 100 comprises a plurality of compute units. Four compute units are shown (104, 106, 108, 110) oriented in tray 112. In this example, each depicted tray holds four compute units, though in other examples, more or fewer compute units may be comprised in some or all trays. For example, the compute units may be hardware accelerator units such as GPUs, tensor processing units (TPUs), or field programmable gate array (FPGA) units. Alternatively, the compute units may be central processing units (CPUs) of server devices. If desired, a mix of these or other types of compute units may be utilized within the computing device assembly 100.

Tray 112 is one of a plurality of trays that are horizontally oriented and mounted within rack 102 in a first vertical stack 114 and a second vertical stack 120. First vertical stack 114 has an exterior side 116 and an interior side 118. The interior side 118 of each tray comprises a plurality of data connectors that receive signals output by compute units, such as compute units 104, 106, 108, and 110. The outer dimensions of each tray 112 are typically the same.

Similarly, second vertical stack 120 has an exterior side 122 and an interior side 124. Interior side 124 comprises a plurality of data connectors that receive signals output by the compute units of the trays of second vertical stack 120.

Computing device assembly 100 comprise a plurality of switches 126 that are vertically oriented and mounted along rack 102 in a first bank of switches 128 and a second bank of switches 130, in one of a plurality of groups positioned at respective vertical levels. First bank of switches 128 has an exterior facing side 128a and an interior facing side 128b. Second bank of switches 130 has an exterior facing side 130a and an interior facing side 130b.

In the depicted embodiment, each bank of switches comprises two groups of seven switches, each group at a different level in the vertical dimension of rack 102. As will be described further herein, he data connections for the switches 126 are formed on interior facing side 128b of switches 126. Switches 126 are generally the same size, each being elongated in the depth and vertical dimensions of the rack 102, as mounted.

Computing device assembly 100 comprises a first set of horizontal cable backplanes 132 mounted in a first vertical array 134 along interior side 118 of first vertical stack 114. The first set of horizontal cable backplanes 132 are mounted in a vertical stack along rack 102, each horizontal cable backplane 132 containing cables that electrically interconnect the data connections on the compute units from trays 112. The data connections for the first set of horizontal cable backplanes 132 are positioned to face the data connections on the interior side (e.g., 118) of the trays 112.

Computing device assembly 100 further comprises a second set of horizontal cable backplanes 136 mounted in a second vertical array 138 along the interior side 124 of second vertical stack 120. Each horizontal cable backplane 136 contains cables that electrically interconnect the data connections on the compute units from trays 112. The data connections for the second set of horizontal cable backplanes 136 are positioned to face the data connections on the interior side (e.g., 124) of the trays 112.

Trays 112 are mounted in a manner such that the interior faces of the trays are inset a predetermined distance from the rear of the rack 102, thus providing space for horizontal cable backplanes 136. The two vertical stacks 114 and 120 of trays 112 are spaced apart in a lateral dimension by a gap within which other components, discussed below, are placed. Trays 112 have a rectangular plate shape, and are elongated in the lateral dimension and depth dimension.

Computing device assembly 100 further comprises a central switch distribution column 140 communicatively coupled to first set of horizontal cable backplanes 132 and to second set of horizontal cable backplanes 136 and to the first bank of switches 128 and the second bank of switches 130, such that each of the plurality of compute units is connected to each of the plurality of switches 126. Here, one central switch distribution column is used for all connections, but two or more smaller modules could alternatively be used.

Central switch distribution column 140 includes cables that electrically interconnect data connections of each of a plurality of data connections on a corresponding switch from each of the first bank of switches 128 and the second bank of switches 130 to corresponding data connections on each of the first set of horizontal cable backplanes 132 and to second set of horizontal cable backplanes 136.

Data connections on central switch distribution column face the interior sides 128b and 130b of first bank of switches 128 and the second bank of switches 130, respectively. In this example, the central switch distribution column 140 is positioned substantially normal to the first and second sets of horizontal cable backplanes (132, 136). The first set of horizontal cable backplanes 132 is mounted between the interior side 118 of the first vertical stack 116 and the first bank of switches 128. The second set of horizontal cable backplanes 136 is mounted between the interior side 124 of the second vertical stack 122 and the second bank of switches 130. Central switch distribution column 140 is positioned between the first bank of switches 128 and the second bank of switches 130.

Switch units plug into central switch distribution column 140 from the sides (e.g., from exterior facing side 128a to interior facing side 128b). The horizontal cable backplanes may be side inserted into central switch distribution column 140. Central switch distribution column 140 may be fixed in rack 102, and may thus require the removal of all switches, trays, and horizontal cable backplanes to be removed first prior to servicing.

Computing device assembly 100 further comprises a third vertical stack 142 of trays of compute units. Third vertical stack 142 has an exterior side 144 and an interior side 146. Interior side 146 comprises a plurality of connectors that receive signals output by the compute units of the trays of third vertical stack 142. A third set of horizontal cable backplanes 148 is mounted in a third vertical array 150 along the interior side 146 of the third vertical stack 142.

Computing device assembly 100 further comprises a fourth vertical stack 152 of trays of compute units. Fourth vertical stack 152 has an exterior side 154 and an interior side 156. Interior side 156 comprises a plurality of connectors that receive signals output by the compute units of the trays of fourth vertical stack 152. A fourth set of horizontal cable backplanes 158 is mounted in a fourth vertical array 160 along the interior side 156 of the fourth vertical stack 152.

Central switch distribution column 140 is communicatively coupled to the third set of horizontal cable backplanes 148 and the fourth set of horizontal cable backplanes 158 such that each of the plurality of compute units is connected to each of the plurality of switches 126. In this example, central switch distribution column 140 is positioned substantially normal to both the third set of horizontal cable backplanes 148 and the fourth set of horizontal cable backplanes 158.

The third set of horizontal cable backplanes 148 is mounted between the interior side 146 of the third vertical stack 142 and the first bank of switches 128. The fourth set of horizontal cable backplanes 158 is mounted between the interior side 156 of the fourth vertical stack 152 and the second bank of switches 130.

Each quadrant of computing device assembly is shown to comprise 32 trays of 4 compute units and 32 horizontal cable backplanes for a total of 512 compute units. However, it will be appreciated that other numbers of compute units and horizontal cable backplanes may be provided in other configurations of the computing device assembly 100. Computing device assembly 100 thus has four vertical stacks of trays of compute units, four horizontal cable backplanes, two banks of switches, and a central switch distribution column arranged in an H-shaped form factor.

In some examples, computing device assembly 100 may be configured as half switched (e.g., 512 compute units, 128 switched links). In other examples, computing device assembly 100 may be configured as full switched (e.g., 384 compute units, 256 switched links). However computing device assembly 100 may be scaled up and scaled out to allow for interconnect protocol flexibility, such as supporting one or more of unified and split topologies.

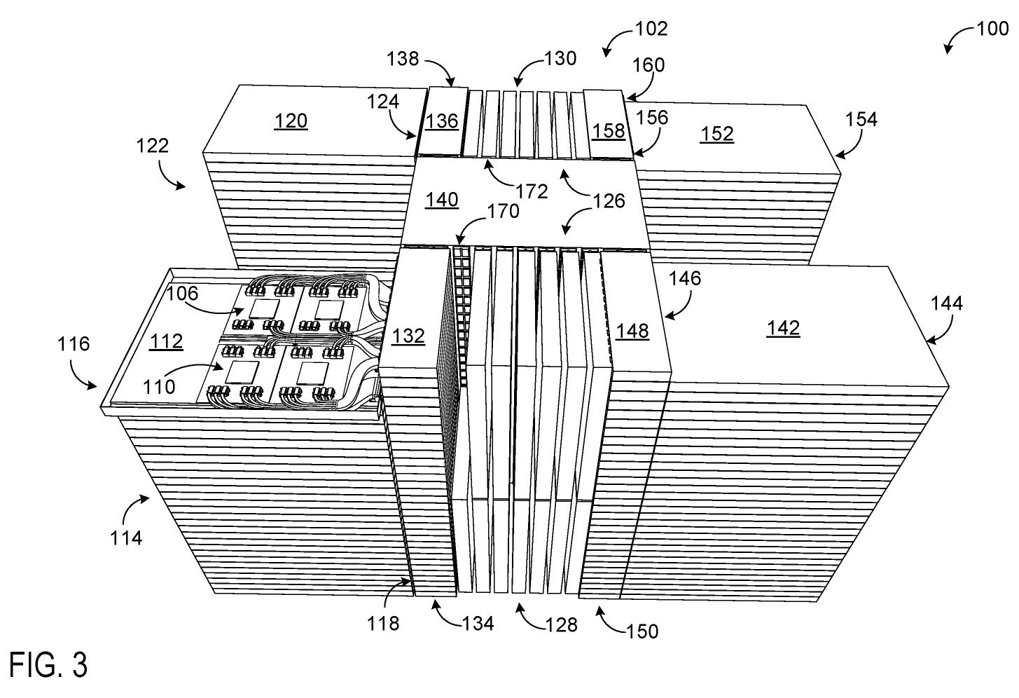

Cabling is typically in the form of shielded copper wire, although other cabling may be used. As indicated in FIG. 6, each compute unit is connected to compute unit backplane data connectors 162. Compute unit backplane data connectors 162 are configured to couple to respective backplane compute side data connectors 164, as shown in FIGS. 2, 4, and 6. In this non-limiting example, 13 backplane compute side data connectors 164 are shown per horizontal cable backplane. Cabling is provided within each horizontal cable backplane to couple backplane compute side data connectors 164 to backplane central side data connectors 166, as shown in FIG. 2. Backplane central side data connectors 166 are configured to couple to respective central backplane side data connectors 168 as shown in FIG. 2. Cabling is provided within central switch distribution column 140 to couple central backplane side data connectors 168 to central switch side data connectors 170 as indicated in FIG. 3. Central switch side data connectors 170 are configured to couple to respective switch central side data connectors 172, as shown in FIG. 3. In this non-limiting example, two rows of 16 connectors are shown. It will be appreciated that compute unit backplane data connectors are thus connected by cabling to switch central side data connectors 172 in a many-to-many fashion.

By providing a central switch distribution column with cabling connecting each of the switches to each of the respective backplane central side data connectors 166, the combination of the horizontal cable backplanes and central switch distribution column (which acts in some fashion as a vertical backplane) enables the switches to route requests and responses to and from any of the compute units of computing device assembly 100. This size and configuration of the horizontal cable backplanes, the central switch distribution column, compute units, and switches, enables data transfer rates on the order of 100 gigabit per second and higher using a passive channel.

Each of the horizontal cable backplanes are essentially identical. Their job is to take the connections from one tray of compute units (e.g., compute backplane data connectors 162) and bring them to the central switch distribution column 140. Central switch distribution column 140 is tasked with connecting each lane to the appropriate switch level, fanning out connections to switches in both vertical and horizontal dimensions. So rather than one large horizontal cable backplane, there is one per tray (e.g., 32 for each vertical column of 32 trays). Each horizontal cable backplane can thus be a smaller, removable module, and each tray 112 can just slide into place, with compute unit backplane data connectors 162 coupling to respective backplane compute side data connectors 164. Given 512 compute units, a 512-lane switching apparatus may be used with 128 switches, and thus 4 lanes connected from every accelerator to each switch. A switch component may have multiple application specific integrated circuits (ASICS) in it. For example a switch assembly may have 4 switch ASICS in each switch with 512 lane switching capabilities.

The unique challenge in such systems is that every compute unit has to talk to every switch. Possibly thousands or even tens of thousands of differential pairs have to crisscross from the compute units and fan out to each switch. This yields a very complicated cable mesh. Further, to maintain high link speeds over copper wires, the cable distance is limited to being on the order of 2-3 meters, while connecting the upper compute units to the lower switches (and vice versa) requires some cabling to extend from the top of the array to the bottom.

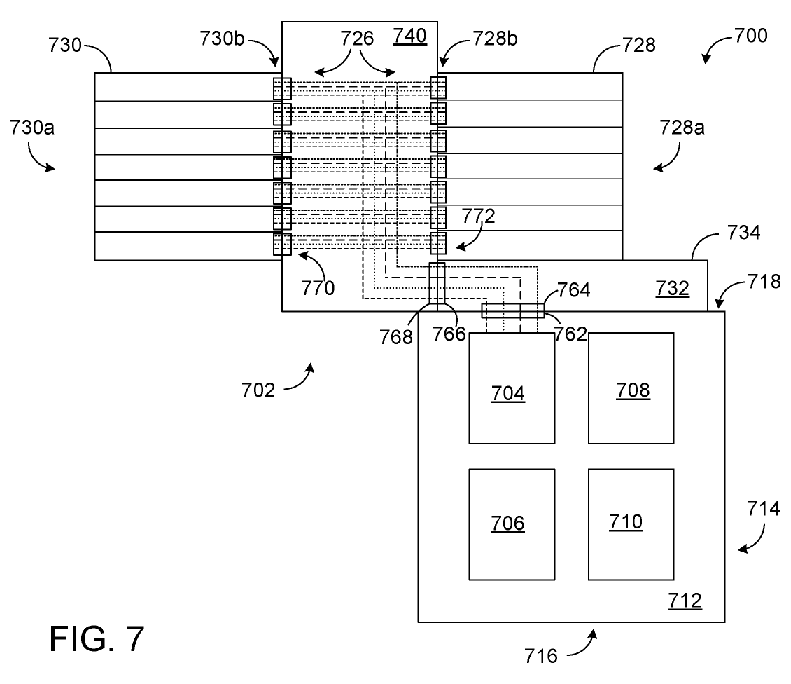

FIG. 7 shows an example wiring routing diagram for an example computing device assembly 700. Computing device assembly 700 may be an example of computing device assembly 100. Similar components are described using similar naming conventions.

Computing device assembly 700 comprises rack 702 defining a volume. Computing device assembly 700 comprises a plurality of compute units. Four compute units are shown (704, 706, 708, 710) oriented in tray 712. Tray 712 is one of a plurality of trays that are horizontally oriented and mounted within rack 702 in a first vertical stack 714. First vertical stack 714 has an exterior side 716 and an interior side 718. For simplicity, only first vertical stack 714 is depicted. However, as described for computing device assembly 100, up to four vertical stacks may be included in computing device assembly 700.

Computing device assembly 700 comprise a plurality of switches 726 that are vertically oriented and mounted along rack 702 in a first bank of switches 728 and a second bank of switches 730, in one of a plurality of groups positioned at respective vertical levels. First bank of switches 728 has an exterior facing side 728a and an interior facing side 728b. Second bank of switches 730 has an exterior facing side 730a and an interior facing side 730b.

Computing device assembly 700 comprises a first set of horizontal cable backplanes 732 mounted in a first vertical array 734 along interior side 718 of first vertical stack 714. Computing device assembly 700 further comprises a central switch distribution column 740 communicatively coupled to first set of horizontal cable backplanes and to the first bank of switches 728 and the second bank of switches 730, such that each of the plurality of compute units is connected to each of the plurality of switches 726.

Each tray 712 has a number of compute units (e.g., 4). While shown as four single wires emanating from compute unit 704, these may actually be very large cable assemblies comprising 64 to 128 lanes (128 to 256 differential pairs). Lanes emanate from board mount connectors and are grouped into harnesses. Each harness couples to a compute unit backplane data connector 762, which then couples to a respective backplane compute side data connector 764. Each lane comprises two differential pairs, each of which comprises a pair of conductor wires (+/-). One differential pair is used as a transmit bundle, the other is used as a receive bundle.

The horizontal back plane essentially acts as an L bracket adapter between tray 712 and central switch distribution column 740, allowing the cabling to internally make a 90-degree turn to reach backplane central side data connectors 766. Backplane central side data connectors 766 then plug in to respective central backplane side data connectors 768.

Signals are thus output by the compute units and transmitted through differential pairs, connecting to the horizontal cable backplanes. The output signals are then routed to the central switch distribution column, where they fan out to couple to each central switch side data connector 770. Although shown in two dimensions, the central switch distribution column necessarily fans cables in three dimensions to reach upper and lower switches. Central switch side data connectors 770 then plug into switch central side data connectors 772, and thus compute unit 704 is communicatively coupled to each switch. As a non-limiting example, there may be 128 switched links. There are thus 64 lanes coupling to first bank of switches 728 and 64 lanes coupling to second bank of switches 730. Each lane has a transmit and receive differential pair. For example, there may be 128 lanes and 256 differential pairs. If there are 128 lanes coming off a tray, those lanes will be divided among the total switches. For example, for 128 lanes and 64 switches there will be 2 lanes per switch.

Herein, all of the switches are rotated 90 degrees from the central switch distribution column. As such, the worst-case distance for each lane does not increase, even though the compute unit count is doubled. The distance along the horizontal dimension is maintained, while the packaging at the central switch distribution column allows for the cables to fan out to the first and second banks of switches.

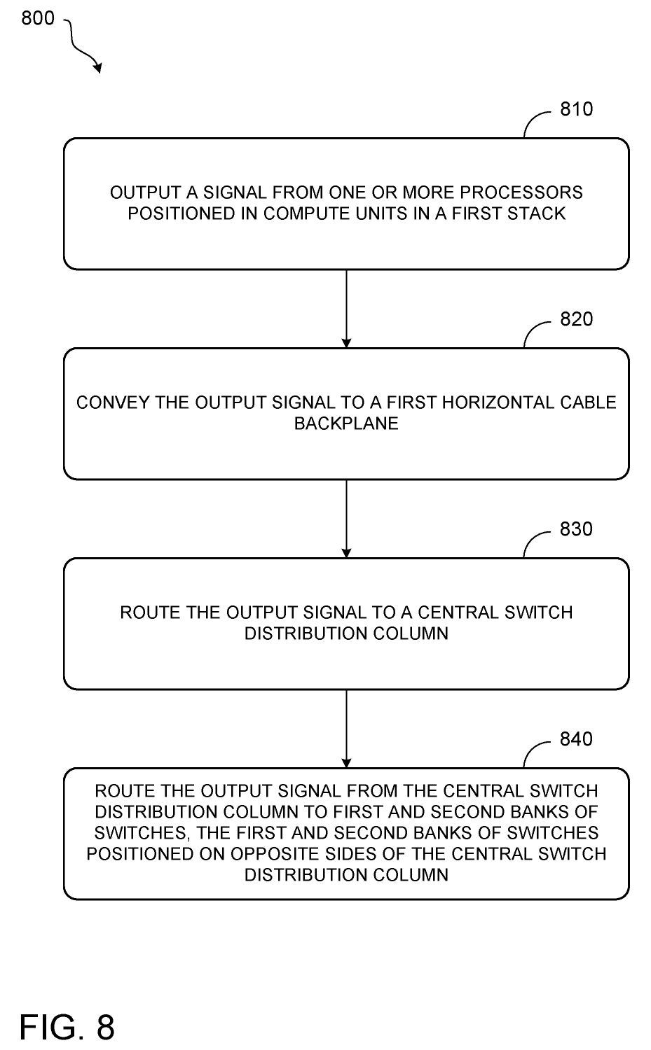

FIG. 8 shows a flow diagram for an example method 800 for operating a computing device assembly, such as computing device assemblies 100 and 700. Although described with regard to computing device assembly 100 and FIG. 1, method 800 is not limited to such an implementation.

At 810, method 800 comprises outputting a signal from one or more processors positioned in compute units (e.g., compute units 104, 106, 108, 110) in a first stack (e.g., first vertical stack 114). At 820, method 800 comprises conveying the output signal to a first horizontal cable backplane (e.g., from first set of horizontal cable backplanes 132). At 830, method 800 comprises routing the output signal to a central switch distribution column (e.g., central switch distribution column 140). At 840, method 800 comprises routing the output signal from the central switch distribution column to first and second banks of switches (e.g., first bank of switches 128 and second bank of switches 130) positioned on opposite sides of the central switch distribution column.

In some such examples, method 800 further comprises outputting a second signal from one or more processors positioned in compute units in a second stack (e.g., second vertical stack 120). The second output signal may be conveyed to a second horizontal cable backplane (e.g., from second set of horizontal cable backplanes 136). The second output signal may be routed to the central switch distribution column (e.g., central switch distribution column 140). The second output signal may then be routed from the central switch distribution column to the first and second banks of switches (e.g., first bank of switches 128 and second bank of switches 130).

In some such examples, method 800 further comprises outputting a third signal from one or more processors positioned in compute units in a third stack (e.g., third vertical stack 142). The third output signal may be conveyed to a third horizontal cable backplane (e.g., from third set of horizontal cable backplanes 148). The third output signal may be routed to the central switch distribution column (e.g., central switch distribution column 140). The third output signal may then be routed from the central switch distribution column to the first and second banks of switches (e.g., first bank of switches 128 and second bank of switches 130).

In some such examples, method 800 further comprises outputting a fourth signal from one or more processors positioned in compute units in a fourth stack (e.g., fourth vertical stack 152). The fourth output signal may be conveyed to a fourth horizontal cable backplane (e.g., from fourth set of horizontal cable backplanes 158). The fourth output signal may be routed to the central switch distribution column (e.g., central switch distribution column 140). The fourth output signal may then be routed from the central switch distribution column to the first and second banks of switches (e.g., first bank of switches 128 and second bank of switches 130).

In some such examples, the first horizontal cable backplane is on an opposite side of the first bank of switches from the third horizontal cable backplane. The second horizontal cable backplane may be on an opposite side of the second bank of switches from the fourth horizontal cable backplane.

In some embodiments, the methods and processes described herein may be tied to a computing system of one or more computing devices. In particular, such methods and processes may be implemented as a computer-application program or service, an application-programming interface (API), a library, and/or other computer-program product.

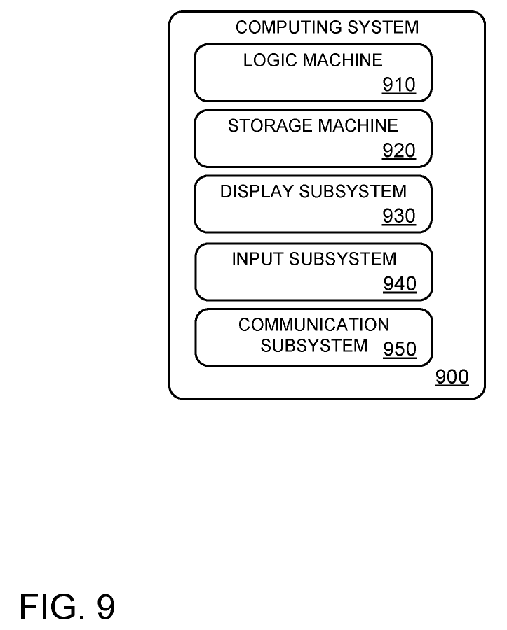

FIG. 9 schematically shows a non-limiting embodiment of a computing system 900 that can enact one or more of the methods and processes described above. Computing system 900 is shown in simplified form. Computing system 900 may take the form of one or more personal computers, server computers, tablet computers, home-entertainment computers, network computing devices, gaming devices, mobile computing devices, mobile communication devices (e.g., smart phone), and/or other computing devices.

Computing system 900 includes a logic machine 910 and a storage machine 920. Computing system 900 may optionally include a display subsystem 930, input subsystem 940, communication subsystem 950, and/or other components not shown in FIG. 9. Computing device assemblies 100 and 700 are examples of computing system 900.

Logic machine 910 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 920 includes one or more physical devices configured to hold instructions executable by the logic machine to implement the methods and processes described herein. When such methods and processes are implemented, the state of storage machine 920 may be transformed—e.g., to hold different data.

Storage machine 920 may include removable and/or built-in devices. Storage machine 920 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine ?? may include volatile, nonvolatile, dynamic, static, read/write, read-only, random-access, sequential-access, location-addressable, file-addressable, and/or content-addressable devices.

It will be appreciated that storage machine 920 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 910 and storage machine 920 may be integrated together into one or more hardware-logic components. Such hardware-logic components may include field-programmable gate arrays (FPGAs), program- and application-specific integrated circuits (PASIC / ASICs), program- and application-specific standard products (PSSP / ASSPs), system-on-a-chip (SOC), and complex programmable logic devices (CPLDs), for example.

The terms “module,” “program,” and “engine” may be used to describe an aspect of computing system 900 implemented to perform a particular function. In some cases, a module, program, or engine may be instantiated via logic machine 910 executing instructions held by storage machine 920. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

It will be appreciated that a “service”, as used herein, is an application program executable across multiple user sessions. A service may be available to one or more system components, programs, and/or other services. In some implementations, a service may run on one or more server-computing devices.

When included, display subsystem 930 may be used to present a visual representation of data held by storage machine 920. This visual representation may take the form of a graphical user interface (GUI). As the herein described methods and processes change the data held by the storage machine, and thus transform the state of the storage machine, the state of display subsystem 930 may likewise be transformed to visually represent changes in the underlying data. Display subsystem 930 may include one or more display devices utilizing virtually any type of technology. Such display devices may be combined with logic machine 910 and/or storage machine 920 in a shared enclosure, or such display devices may be peripheral display devices.

When included, input subsystem 940 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity.

When included, communication subsystem 950 may be configured to communicatively couple computing system 900 with one or more other computing devices. Communication subsystem 950 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 900 to send and/or receive messages to and/or from other devices via a network such as the Internet.

In one example, a computing device assembly is presented. The computing device assembly comprises a rack; a plurality of compute units that are horizontally oriented and mounted within the rack in a first vertical stack and a second vertical stack; a plurality of switches that are vertically oriented and mounted along the rack in a first bank of switches and a second bank of switches; a first set of horizontal cable backplanes mounted in a first vertical array along an interior side of the first vertical stack; a second set of horizontal cable backplanes mounted in a second vertical array along an interior side of the second vertical stack; and a central switch distribution column communicatively coupled to the first and second sets of horizontal cable backplanes and to the first and second banks of switches, such that each of the plurality of compute units is connected to each of the plurality of switches through the central switch distribution column. In some such examples, or any other example, the central switch distribution column is additionally or alternatively positioned substantially normal to the first and second sets of horizontal cable backplanes. In any of the preceding examples, or any other example, the first set of horizontal cable backplanes is additionally or alternatively mounted between the interior side of the first vertical stack and the first bank of switches. In any of the preceding examples, or any other example, the second set of horizontal cable backplanes is additionally or alternatively mounted between the interior side of the second vertical stack and the second bank of switches. In any of the preceding examples, or any other example, the central switch distribution column is additionally or alternatively positioned between the first bank of switches and the second bank of switches, such that each compute unit is connected to a switch on opposing sides of the central switch distribution column. In any of the preceding examples, or any other example, the plurality of compute units are additionally or alternatively horizontally oriented and further mounted within the rack in a third vertical stack and a fourth vertical stack, and the computing device assembly additionally or alternatively comprises a third set of horizontal cable backplanes mounted in a third vertical array along an interior side of the third vertical stack; and a fourth set of horizontal cable backplanes mounted in a fourth vertical array along an interior side of the fourth vertical stack. In any of the preceding examples, or any other example, the central switch distribution column is additionally or alternatively communicatively coupled to the third and fourth sets of horizontal cable backplanes such that each of the plurality of compute units is connected to each of the plurality of switches. In any of the preceding examples, or any other example, the central switch distribution column is additionally or alternatively positioned substantially normal to the third and fourth sets of horizontal cable backplanes. In any of the preceding examples, or any other example, the computing device assembly additionally or alternatively comprises a plurality of trays, each tray comprising four compute units. In any of the preceding examples, or any other example, each horizontal cable backplane additionally or alternatively acts as an L-bracket between a tray and the central switch distribution column. In any of the preceding examples, or any other example, each of the plurality of compute units additionally or alternatively comprises one or more graphics processing units. In any of the preceding examples, or any other example, each compute unit is additionally or alternatively connected to each switch via two or more lanes. In any of the preceding examples, or any other example, the central switch distribution column additionally or alternatively fans out connections to switches in both vertical and horizontal dimensions.

In another example, a method for a computing device assembly is presented. The method comprises outputting a signal from one or more processors positioned in compute units in a first stack; conveying the output signal to a first horizontal cable backplane; routing the output signal to a central switch distribution column; and routing the output signal from the central switch distribution column to first and second banks of switches, the first and second banks of switched positioned on opposite sides of the central switch distribution column. In some such examples, or any other example, the method additionally or alternatively comprises outputting a second signal from one or more processors positioned in compute units in a second stack; conveying the second output signal to a second horizontal cable backplane; routing the second output signal to the central switch distribution column; and routing the second output signal from the central switch distribution column to the first and second banks of switches. In any of the preceding examples, or any other example, the method additionally or alternatively comprises outputting a third signal from one or more processors positioned in compute units in a third stack; conveying the third output signal to a third horizontal cable backplane; routing the third output signal to the central switch distribution column; and routing the third output signal from the central switch distribution column to the first and second banks of switches. In any of the preceding examples, or any other example, the method additionally or alternatively comprises outputting a fourth signal from one or more processors positioned in compute units in a fourth stack; conveying the fourth output signal to a fourth horizontal cable backplane; routing the fourth output signal to the central switch distribution column; and routing the fourth output signal from the central switch distribution column to the first and second banks of switches. In any of the preceding examples, or any other example, the first horizontal cable backplane is additionally or alternatively on an opposite side of the first bank of switches from the third horizontal cable backplane, and wherein the second horizontal cable backplane is additionally or alternatively on an opposite side of the second bank of switches from the fourth horizontal cable backplane.

In yet another example, a computing device assembly is presented. The computing device assembly comprises a rack; a plurality of compute units that are horizontally oriented and mounted within the rack in a first vertical stack, a second vertical stack, a third vertical stack, and a fourth vertical stack; a plurality of switches that are vertically oriented and mounted along the rack in a first bank of switches and a second bank of switches; a first set of horizontal cable backplanes mounted in a first vertical array along an interior side of the first vertical stack; a second set of horizontal cable backplanes mounted in a second vertical array along an interior side of the second vertical stack; a third set of horizontal cable backplanes mounted in a third vertical array along an interior side of the third vertical stack; a fourth set of horizontal cable backplanes mounted in a fourth vertical array along an interior side of the fourth vertical stack; and a central switch distribution column communicatively coupled to the first, second, third, and fourth sets of horizontal cable backplanes and to the first and second banks of switches, such that each of the plurality of compute units is connected to each of the plurality of switches through the central switch distribution column. In some such examples, or any other example, the central switch distribution column is additionally or alternatively positioned substantially normal to the first, second, third, and fourth sets of horizontal cable backplanes; the first set of horizontal cable backplanes is additionally or alternatively mounted between the interior side of the first vertical stack and the first bank of switches; the second set of horizontal cable backplanes is additionally or alternatively mounted between the interior side of the second vertical stack and the second bank of switches; the third set of horizontal cable backplanes is additionally or alternatively mounted between the interior side of the third vertical stack and the first bank of switches; the fourth set of horizontal cable backplanes is additionally or alternatively mounted between the interior side of the fourth vertical stack and the second bank of switches; and the central switch distribution column is additionally or alternatively positioned between the first bank of switches and the second bank of switches, such that each compute unit is connected to a switch on opposing sides of the central switch distribution column.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A computing device assembly, comprising:
a rack;
a plurality of compute units that are horizontally oriented and mounted within the rack in a first vertical stack and a second vertical stack;
a plurality of switches that are vertically oriented and mounted along the rack in a first bank of switches and a second bank of switches;
a first set of horizontal cable backplanes mounted in a first vertical array along an interior side of the first vertical stack;
a second set of horizontal cable backplanes mounted in a second vertical array along an interior side of the second vertical stack; and
a central switch distribution column communicatively coupled to the first and second sets of horizontal cable backplanes and to the first and second banks of switches, such that each of the plurality of compute units is connected to each of the plurality of switches through the central switch distribution column.

2. The computing device assembly of claim 1, wherein the central switch distribution column is positioned substantially normal to the first and second sets of horizontal cable backplanes.

3. The computing device assembly of claim 2, wherein the first set of horizontal cable backplanes is mounted between the interior side of the first vertical stack and the first bank of switches.

4. The computing device assembly of claim 2, wherein the second set of horizontal cable backplanes is mounted between the interior side of the second vertical stack and the second bank of switches.

5. The computing device assembly of claim 2, wherein the central switch distribution column is positioned between the first bank of switches and the second bank of switches, such that each compute unit is connected to a switch on opposing sides of the central switch distribution column.

6. The computing device assembly of claim 1, wherein the plurality of compute units are horizontally oriented and further mounted within the rack in a third vertical stack and a fourth vertical stack, the computing device assembly further comprising:
a third set of horizontal cable backplanes mounted in a third vertical array along an interior side of the third vertical stack; and
a fourth set of horizontal cable backplanes mounted in a fourth vertical array along an interior side of the fourth vertical stack.

7. The computing device assembly of claim 6, wherein the central switch distribution column is communicatively coupled to the third and fourth sets of horizontal cable backplanes such that each of the plurality of compute units is connected to each of the plurality of switches.

8. The computing device assembly of claim 6, wherein the central switch distribution column is positioned substantially normal to the third and fourth sets of horizontal cable backplanes.

9. The computing device assembly of claim 1, further comprising a plurality of trays, each tray comprising four compute units.

10. The computing device assembly of claim 9, wherein each horizontal cable backplane acts as an L-bracket between a tray and the central switch distribution column.

11. The computing device assembly of claim 1, wherein each of the plurality of compute units comprises one or more graphics processing units.

12. The computing device assembly of claim 1, wherein each compute unit is connected to each switch via two or more lanes.

13. The computing device assembly of claim 1, wherein the central switch distribution column fans out connections to switches in both vertical and horizontal dimensions.

14. A method for a computing device assembly, comprising:
outputting a signal from one or more processors positioned in compute units in a first stack;
conveying the output signal to a first horizontal cable backplane;
routing the output signal to a central switch distribution column; and
routing the output signal from the central switch distribution column to first and second banks of switches, the first and second banks of switched positioned on opposite sides of the central switch distribution column.

15. The method of claim 14, further comprising:
outputting a second signal from one or more processors positioned in compute units in a second stack;
conveying the second output signal to a second horizontal cable backplane;
routing the second output signal to the central switch distribution column; and
routing the second output signal from the central switch distribution column to the first and second banks of switches.

16. The method of claim 15, further comprising:
outputting a third signal from one or more processors positioned in compute units in a third stack;
conveying the third output signal to a third horizontal cable backplane;
routing the third output signal to the central switch distribution column; and
routing the third output signal from the central switch distribution column to the first and second banks of switches.

17. The method of claim 16, further comprising:
outputting a fourth signal from one or more processors positioned in compute units in a fourth stack;
conveying the fourth output signal to a fourth horizontal cable backplane;
routing the fourth output signal to the central switch distribution column; and
routing the fourth output signal from the central switch distribution column to the first and second banks of switches.

18. The method of claim 17, wherein the first horizontal cable backplane is on an opposite side of the first bank of switches from the third horizontal cable backplane, and wherein the second horizontal cable backplane is on an opposite side of the second bank of switches from the fourth horizontal cable backplane.

19. A computing device assembly, comprising:
a rack;
a plurality of compute units that are horizontally oriented and mounted within the rack in a first vertical stack, a second vertical stack, a third vertical stack, and a fourth vertical stack;
a plurality of switches that are vertically oriented and mounted along the rack in a first bank of switches and a second bank of switches;
a first set of horizontal cable backplanes mounted in a first vertical array along an interior side of the first vertical stack;
a second set of horizontal cable backplanes mounted in a second vertical array along an interior side of the second vertical stack;
a third set of horizontal cable backplanes mounted in a third vertical array along an interior side of the third vertical stack;
a fourth set of horizontal cable backplanes mounted in a fourth vertical array along an interior side of the fourth vertical stack; and
a central switch distribution column communicatively coupled to the first, second, third, and fourth sets of horizontal cable backplanes and to the first and second banks of switches, such that each of the plurality of compute units is connected to each of the plurality of switches through the central switch distribution column.

20. The computing device assembly of claim 19, wherein
the central switch distribution column is positioned substantially normal to the first, second, third, and fourth sets of horizontal cable backplanes;
the first set of horizontal cable backplanes is mounted between the interior side of the first vertical stack and the first bank of switches;
the second set of horizontal cable backplanes is mounted between the interior side of the second vertical stack and the second bank of switches;
the third set of horizontal cable backplanes is mounted between the interior side of the third vertical stack and the first bank of switches;
the fourth set of horizontal cable backplanes is mounted between the interior side of the fourth vertical stack and the second bank of switches; and
the central switch distribution column is positioned between the first bank of switches and the second bank of switches, such that each compute unit is connected to a switch on opposing sides of the central switch distribution column.
